(19) United States
(12) Patent Application Publication
(10) Pub. No.: US 2026/0334135 A1
(43) Pub. Date: Oct. 22, 2026

(54) WAFER PROCESSING SYSTEM AND WAFER PROCESSING METHOD

(71) Applicant: Tokyo Seimitsu Co., Ltd., Tokyo (JP)

(72) Inventors: Katsufumi Moriyama, Ibaraki (JP); Yoshiyuki Kawata, Ibaraki (JP); Natsumi Hayashi, Ibaraki (JP); Hideki Morii, Ibaraki (JP)

(21) Appl. No.: 19/704,661

(22) Filed: Jun. 11, 2026

Related U.S. Application Data
(63) Continuation of application No. PCT/JP2024/043154, filed on Dec. 6, 2024.

(30) Foreign Application Priority Data
Dec. 11, 2023 (JP) 2023-208637

(51) Int. Cl. H10P 72/00; B24B 7/22; B24B 49/04; B24B 49/12

(52) U.S. Cl. CPC H10P 72/0428; B24B 7/228; B24B 49/04; B24B 49/12; H10P 72/0604; H10P 72/0616

(57) ABSTRACT

A wafer processing system includes: a grinding section configured to perform grinding of an edge portion of a wafer; a measurement section configured to measure a shape of the edge portion of the wafer subjected to the grinding, the measurement section being configured to measure a shape of a tip portion of a truer used for the grinding; and a feedback calculation section configured to perform feedback control for the grinding based on a measurement result the shape of the tip portion of the truer.

### CROSS-REFERENCE TO RELATED APPLICATIONS

The present application is a Continuation of PCT International Application No. PCT/JP2024/043154 filed on Dec. 6, 2024 claiming priority under 35 U.S.C. § 119(a) to Japanese Patent Application No. 2023-208637 filed on Dec. 11, 2023. Each of the above applications is hereby expressly incorporated by reference, in its entirety, into the present application.

### BACKGROUND OF THE INVENTION

### Field of the Invention

The present invention relates to a wafer processing system and a wafer processing method and, more particularly, to a wafer processing system and a wafer processing method for processing an edge portion of a wafer.

### Description of the Related Art

In surface processing of a disc-shaped wafer by a polishing apparatus, an edge portion of the wafer is processed into a sharp shape. This may cause cracking or chipping of the wafer. For this reason, a wafer is subjected to grinding (also referred to as chamfering) in order to remove a sharp portion at an edge portion of a wafer and form the edge portion into a round shape or a chamfered shape (see Patent Literature 1).

Since a shape and dimensions of an edge portion of a wafer shaped by grinding are specified by industry standards or customer requirements, the edge portion must be ground within the specified tolerances. From this, in a wafer manufacturing process, a shape of an edge portion of a wafer is measured after grinding. Shape measurement is performed for checking whether the shape of the edge portion falls within a specified tolerances.

Patent Literature 2 discloses a shape measuring apparatus that measures a shape of an edge portion of a wafer by a light projection measurement method. The shape measuring apparatus projects light onto an edge portion of a ground wafer from a direction generally parallel to front and back surfaces of the wafer and captures a projection image of the edge portion of the wafer from a direction opposing the light projection direction by a camera. The shape measuring apparatus measures a shape of the edge portion of the wafer based on the projection image.

### CITATION LIST

### Patent Literature(s)

Patent Literature 1: Japanese Patent Application Laid-Open No. 2009-78326

Patent Literature 2: Japanese Patent Application Laid-Open No. 2009-168634

### SUMMARY OF THE INVENTION

In grinding described above, defect (e.g., deviation from a processing target) may occur in a shape of an edge portion of a wafer. For example, a grinding wheel used for grinding is shaped into a target profile by truing a surface of the grinding wheel with a truer to adjust a cross-sectional groove profile. Such a truer deteriorates (becomes worn) through repeated use. When the truer deteriorates, the truer cannot sufficiently adjust the shape of the grinding wheel, which may cause a defect in the shape of the edge portion of the wafer.

The present invention has been made in view of the above-described circumstances, and aims to provide a wafer processing system and a wafer processing method capable of suppress occurrence of defect in a shape of an edge portion of a ground wafer.

In order to achieve the object, the present invention has the following aspects.

A wafer processing system according to a first aspect of the present invention includes: a grinding section configured to perform grinding of an edge portion of a wafer; a measurement section configured to measure a shape of the edge portion of the wafer subjected to grinding, the measurement section being configured to measure a shape of a tip portion of a truer for truing a grinding wheel used for the grinding; and a feedback calculation section configured to perform feedback control for the grinding based on a measurement result of the shape of the tip portion of the truer.

In a wafer processing system according to a second aspect of the present invention, in the first aspect, the feedback calculation section determines whether the truer is defective or not in a case where a wear amount of the truer exceeds a threshold.

In a wafer processing system according to a third aspect of the present invention, in the first or second aspect, the measurement section measures the shape of the tip portion of the truer in a case where the feedback calculation section determines that the shape of the edge portion of the wafer is defective, the feedback calculation section produces output encouraging maintenance of the truer in a case where the feedback calculation section determines that the shape of the tip portion of the truer is defective, and the feedback calculation section produces output encouraging maintenance of the grinding wheel using the truer in a case where the feedback calculation section determines that the shape of the tip portion of the truer is not defective.

A wafer processing system according to a fourth aspect of the present invention, in any one of the first to third aspects, includes an output section configured to display measurement results of the wafer and the truer in a superimposed manner.

In a wafer processing system according to a fifth aspect of the present invention, in any one of the first to fourth aspects, the feedback calculation section compares a measured value and a design value of the shape of the truer and calculates a correction amount for the shape of the truer and a relative movement amount between the wafer and the grinding wheel.

In a wafer processing system according to a sixth aspect of the present invention, in any one of the first to fifth aspects, the measurement section measures a surface roughness of a ground surface of the wafer, and the feedback calculation section adjusts a depth of cut of the grinding wheel into the wafer in accordance with a measurement result of the surface roughness of the ground surface.

In a wafer processing system according to a seventh aspect of the present invention, in any one of the first to sixth aspects, the feedback calculation section adjusts a helical angle of the grinding wheel in accordance with a measurement result of the wafer.

A wafer processing method according to an eighth aspect of the present invention includes: measuring a shape of a tip portion of a truer used for grinding, in a measurement section configured to measure a shape of an edge portion of a wafer subjected to grinding; and perform feedback control for the grinding based on a measurement result of the shape of the tip portion of the truer.

According to the present invention, it is possible to inhibit occurrence of defect in a shape of an edge portion of a ground wafer by performing feedback control in accordance with a measurement result of truer measurement in a measurement section that performs wafer measurement.

### BRIEF DESCRIPTION OF THE DRAWINGS

FIG. 1 is a plan view showing a schematic configuration of a wafer processing system;

FIG. 2 is a schematic configuration view showing a schematic configuration of a grinding apparatus (chamfering apparatus) installed in a grinding section;

FIG. 3 is a side view showing a schematic configuration of a shape measuring apparatus;

FIG. 4 is a plan view showing the schematic configuration of the shape measuring apparatus;

FIG. 5 is a schematic view showing details of a configuration of an optical unit;

FIG. 6 is a functional block diagram of a control device in the shape measuring apparatus;

FIG. 7 is a cross-sectional view showing an example of a shape of a tip portion of a truer;

FIG. 8 is a flowchart showing a wafer processing method according to Example 2;

FIG. 9 is a view showing an output example of results of measuring a wafer and a truer;

FIG. 10 is a view for explaining the cause of defect in a shape of a wafer;

FIG. 11 is a cross-sectional view of a wafer after grinding; and

FIG. 12 is a view for explaining adjustment of a helical angle.

### DESCRIPTION OF THE EMBODIMENTS

An embodiment of the present invention will be described below with reference to the accompanying drawings.

### Wafer Processing System

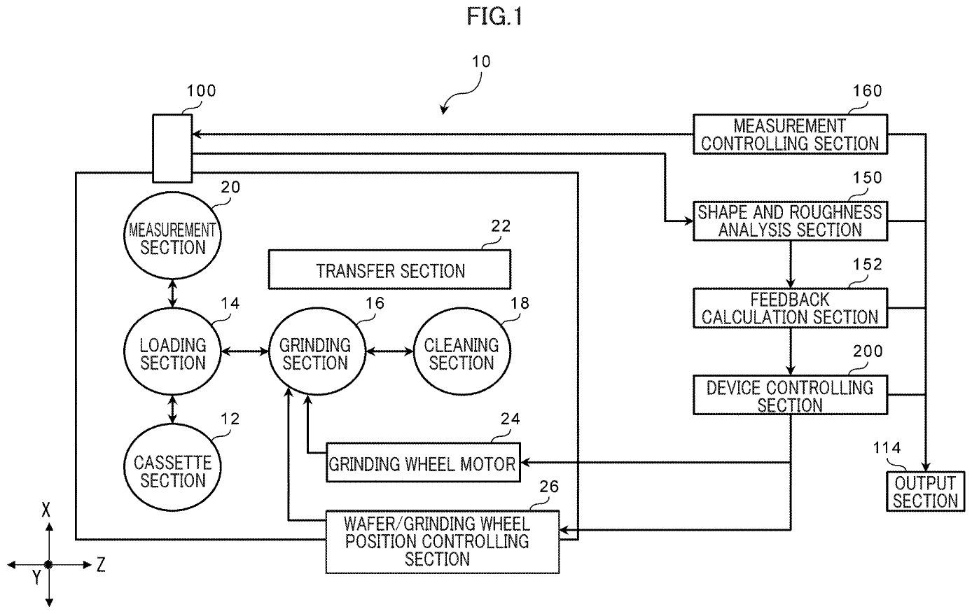

FIG. 1 is a plan view showing a schematic configuration of a wafer processing system 10. In the following description, of three X, Y, and Z directions orthogonal to one another shown in the drawings, the X and Z directions refer to horizontal directions, and the Y direction refers to a vertical direction (perpendicular direction).

As shown in FIG. 1, the wafer processing system 10 includes a cassette section 12, a loading section 14, a grinding section 16, a cleaning section 18, a measurement section 20, and a transfer section 22.

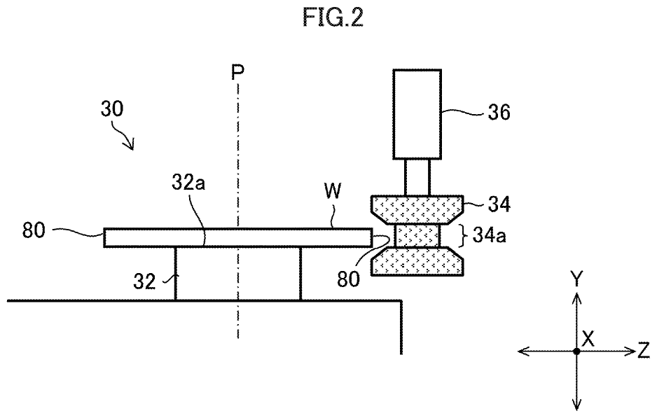

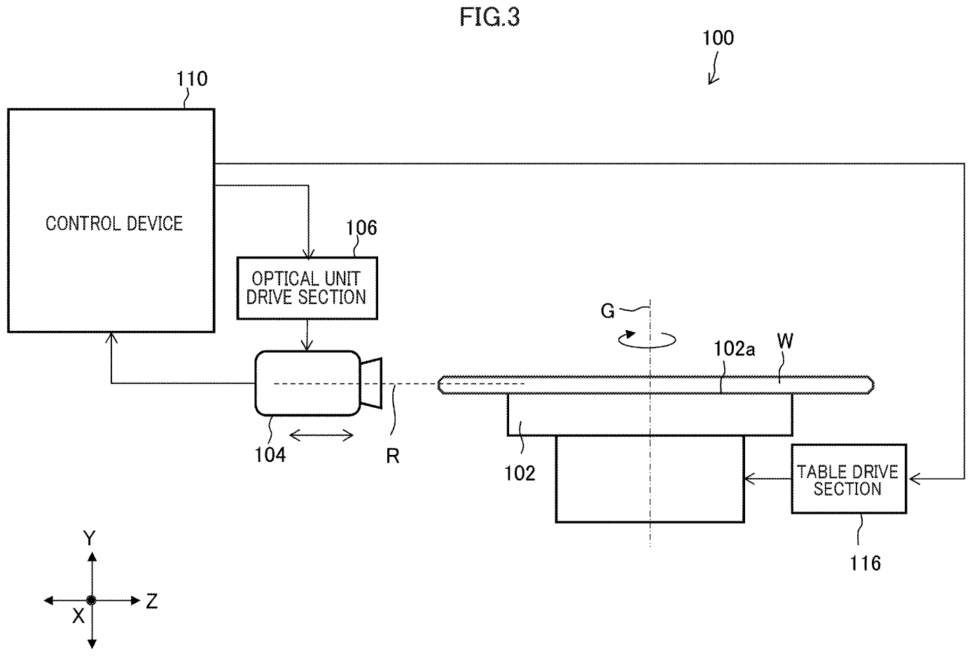

The loading section 14 transports a wafer W (shown in, e.g., FIGS. 2 and 3) between the cassette section 12, the grinding section 16, and the measurement section 20. The operation is performed by a wafer transfer robot (loading/unloading robot). A wafer cassette housing a large number of wafers W to be chamfered is provided in the cassette section 12. The wafer transfer robot takes wafers W one by one out of the wafer cassette or houses a chamfered wafer W in the wafer cassette.

The wafer transfer robot includes a triaxial rotation transport arm, which includes a suction pad (not shown) at an upper surface portion thereof. The transport arm holds a wafer W by adhering to a lower surface of the wafer W by vacuum suction using the suction pad. That is, the transport arm of the wafer transfer robot is capable of to-and-fro movement, up-and-down movement, and turning while holding the wafer W. The transport arm transports the wafer W by combining such operations.

The grinding section 16 performs grinding, i.e., processing from rough processing to finish processing on an edge portion of a wafer W.

FIG. 2 is a schematic configuration view showing a schematic configuration of a grinding apparatus (chamfering apparatus) 30 installed in the grinding section 16. As shown in FIG. 2, the grinding apparatus 30 includes a grinding table 32 which holds a wafer W, a grinding wheel 34, and a spindle motor 36 which rotates the grinding wheel 34.

The grinding table 32 has, at an upper surface, a holding surface 32a which suctions and holds the wafer W. The grinding table 32 is configured to be rotatable around a rotation axis P parallel to the Y direction by an actuator of arbitrary type (not shown), such as a motor drive mechanism.

The grinding wheel 34 is configured to be rotatable around a rotation axis parallel to the Y direction by the spindle motor 36. The grinding wheel 34 is moved to advance and retreat in the Z direction relative to an edge portion of the wafer W held by the grinding table 32. In a case where the grinding wheel 34 is moved to advance, the rotating grinding wheel 34 is relatively pushed against an outer peripheral portion (edge portion 80) which is the edge portion of the rotating wafer W, and the outer peripheral portion of the wafer W is ground. The grinding wheel 34 in the present example is a formed grinding wheel (profile grinding wheel) having a grinding groove 34a at an outer peripheral portion thereof, and a shape of the grinding groove 34a is transferred onto the outer peripheral portion of the wafer W at the time of grinding.

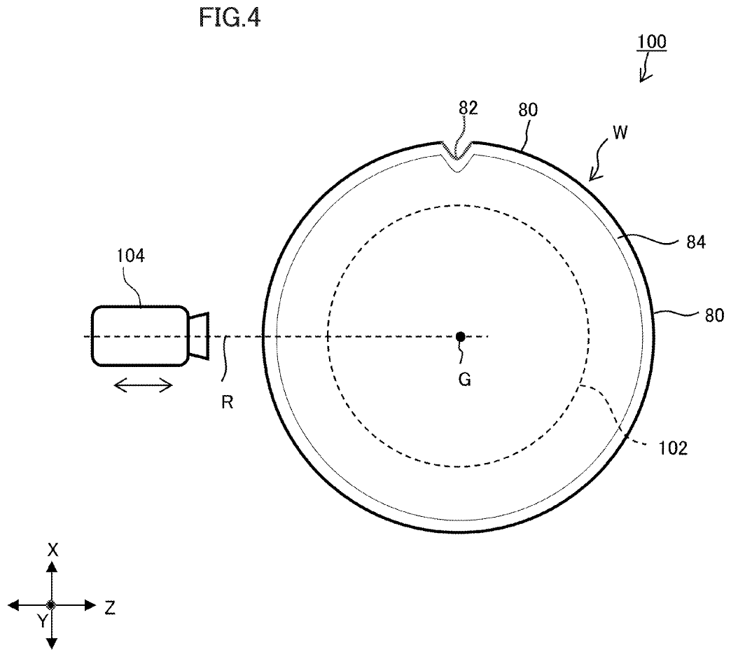

The grinding apparatus 30 is provided with a grinding wheel for precision grinding (not shown), in addition to the grinding wheel (a grinding wheel for rough grinding) 34. With this configuration, after the outer peripheral portion of the wafer W is roughly processed with the grinding wheel 34, chamfering for finish grinding on the outer peripheral portion of the wafer W is executed with the grinding wheel for precision grinding. The grinding apparatus 30 is also provided with a grinding wheel for notch rough grinding and a grinding wheel for notch precision grinding for grinding a notch portion 82 (see FIG. 4). With this provision, after the notch portion 82 is roughly processed with the grinding wheel for notch rough grinding, chamfering as finish grinding is executed on the notch portion 82 with the grinding wheel for notch precision grinding. Note that a plurality of grinding apparatuses 30 may be installed in the grinding section 16.

Referring back to FIG. 1, the cleaning section 18 cleans a wafer W after chamfering. The cleaning section 18 includes a spin cleaning apparatus (not shown). The spin cleaning apparatus sprays a cleaning solution onto an upper surface (surface) of the wafer W while rotating the wafer W held by a cleaning table to remove dirt on the upper surface of the wafer W.

The transfer section 22 transports a wafer W between the grinding section 16 and the cleaning section 18. The transfer section 22 includes a transport robot which is configured to be capable of linear operation in the Z direction and up-and-down operation in the Y direction (perpendicular direction). The transport robot includes an arm portion, and a suction pad is provided at a distal edge portion of the arm portion. The transport robot transports the wafer W with an upper surface of the wafer W suctioned by the suction pad of the arm portion. With this configuration, in the transfer section 22, the transport robot transports a wafer W chamfered in the grinding section 16 to the cleaning section 18 or transports a wafer W cleaned in the cleaning section 18 to the grinding section 16.

The measurement section 20 performs thickness measurement and pre-alignment of a wafer W to be chamfered. The measurement section 20 includes a measurement table (indicated by reference numeral 102 in FIG. 4), a thickness sensor, and an OF/notch detecting sensor to perform the thickness measurement and the pre-alignment of the wafer W.

The measurement table rotates the wafer W around its central axis. The thickness sensor is, for example, a capacitance sensor and measures a distance from an upper surface to a lower surface of the wafer W. A measurement result from the capacitance sensor is output to a calculation device (not shown), and a thickness of the wafer W is obtained. The OF/notch detecting sensor is, for example, a laser sensor and detects a position of an OF or a notch of the wafer W. OF here is an abbreviation for an orientation flat that is a flat portion formed at an edge portion of the wafer W to indicate a crystal orientation of the wafer W, and the notch portion 82 is a notched portion formed to indicate a crystal orientation of a wafer. Examples of the thickness sensor include an interferometric one in addition to one of capacitance type. OF/notch detecting sensors include an image sensor.

The measurement section 20 also includes a diameter gauge (not shown) that measures a diameter of a chamfered wafer W and a shape measuring apparatus 100 (an example of a “shape measuring apparatus” according to the present invention) that measures a three-dimensional shape of an edge portion of the chamfered wafer W. A configuration of the shape measuring apparatus 100 will be described later in detail.

An outline of operation of the wafer processing system 10 according to the embodiment will be described.

A wafer W is first taken out of the cassette attached to the cassette section 12 by the wafer transfer robot of the loading section 14 and is transported to the measurement section 20. The wafer W transported to the measurement section 20 is placed on the measurement table in the measurement section 20.

In the measurement section 20, thickness measurement and pre-alignment of the wafer W are performed using the thickness sensor and the OF/notch detecting sensor. A diameter of the wafer W is measured using the diameter gauge.

The wafer W subjected to various types of measurements in the measurement section 20 is transported to the grinding section 16 by the wafer transfer robot of the loading section 14. The wafer W transported to the grinding section 16 is placed on the grinding table 32 of the grinding apparatus 30.

In the grinding section 16, grinding (chamfering) of an edge portion of the wafer W is performed by the grinding apparatus 30. Specifically, after the edge portion 80 that is an outer peripheral portion of the wafer W is roughly processed with the grinding wheel 34, chamfering for finish grinding of the outer peripheral portion of the wafer W is executed with the grinding wheel for precision grinding. After the notch portion 82 of the wafer W is roughly processed with the grinding wheel for notch rough grinding, chamfering as finish grinding is executed with the grinding wheel for notch precision grinding.

As shown in FIG. 1, the grinding section 16 is provided with a grinding wheel motor 24 and a wafer/grinding wheel position controlling section 26. The grinding wheel motor 24 is a motor for rotating the grinding wheel 34 and the grinding wheel for precision grinding in accordance with a control signal from a device controlling section 200. The wafer/grinding wheel position controlling section 26 includes an actuator for adjusting relative positions between the wafer W and the grinding wheel 34 and grinding wheel for precision grinding (X-, Y-, and Z-direction positions and inclinations of the grinding wheel 34 and the grinding wheel for precision grinding to the wafer W) in accordance with a control signal from the device controlling section 200, and the like. Note that the device controlling section 200 shown in FIG. 1 may be included in a control device 110 including a measurement controlling section 160 and the like, or may be included in a circuit or a control device different from the control device 110. The measurement controlling section 160 and the like will be described later.

The wafer W which has been ground (chamfered) in the grinding section 16 is transported from the grinding section 16 to the cleaning section 18 using the transport robot of the transfer section 22. In the cleaning section 18, the wafer W is cleaned by the spin cleaning apparatus.

The wafer W after the cleaning in the cleaning section 18 is transported from the cleaning section 18 to the grinding section 16 by the transport robot of the transfer section 22. After that, the wafer W is transported from the grinding section 16 to the measurement section 20 by the wafer transfer robot of the loading section 14. The wafer W transported to the measurement section 20 is placed on the measurement table.

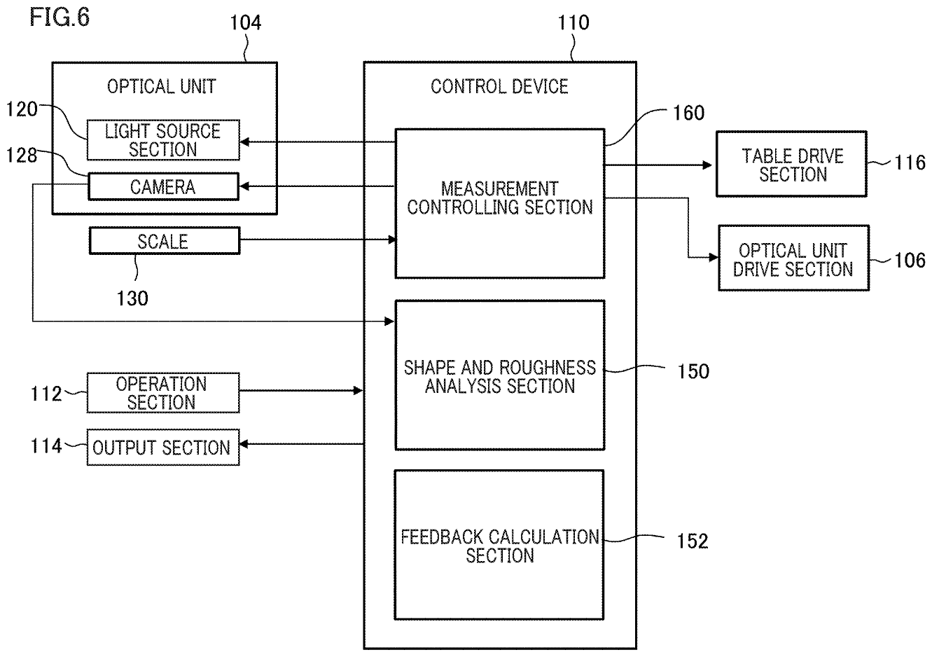

In the measurement section 20, the diameter of the wafer W is measured using the diameter gauge, and a three-dimensional shape of the edge portion of the wafer W is measured by the shape measuring apparatus 100. Measurement results (the diameter of the wafer W and the three-dimensional shape of the edge portion of the wafer W) from the measurement section 20 are output to an output section (indicated by reference numeral 114 in FIG. 6). Note that the control device 110 (to be described later) may calculate a determination result indicating whether the measurement results from the measurement section 20 fall within prescribed ranges determined in advance and output the determination result to the output section.

The wafer W after the measurement in the measurement section 20 is transported from the measurement section 20 to the cassette section 12 by the wafer transfer robot of the loading section 14 and is housed in the cassette.

### Shape Measuring Apparatus

A configuration of the shape measuring apparatus 100 will be described. The shape measuring apparatus 100 calculates three-dimensional shape data indicating height information (e.g., a surface shape and surface roughness) of a surface to be measured at an edge portion of a wafer W as a measurement object based on a plurality of captured images captured at fixed intervals while an optical unit 104 (white-light interference microscope) (to be described later) scans in a scanning direction (Z direction).

FIG. 3 is a side view (a view as seen from the X direction) showing a schematic configuration of the shape measuring apparatus 100. FIG. 4 is a plan view (a view as seen from the Y direction) showing the schematic configuration of the shape measuring apparatus 100.

As shown in FIGS. 3 and 4, the shape measuring apparatus 100 includes the measurement table 102, the optical unit 104, and the control device 110.

The measurement table 102 has, at an upper surface, a holding surface 102a which suctions and holds a wafer W. The measurement table 102 is configured to be rotatable around a rotation axis G parallel to the Y direction. A table drive section 116 includes an actuator of arbitrary type, such as a motor driving mechanism, and rotates the measurement table 102 around the rotation axis G under control by the control device 110 (to be described later). With this rotation, the wafer W suctioned and held by the holding surface 102a of the measurement table 102 moves rotationally around the rotation axis G.

The optical unit 104 includes a white-light interference microscope. The optical unit 104 is provided at a position adjacent to the measurement table 102 on one side (the left side in FIG. 3) of the Z direction. Specifically, the optical unit 104 is disposed such that an optical axis R thereof (corresponding to an optical axis of an interference objective lens 124) is parallel (the term “parallel” as used herein is intended to include the meaning of “generally parallel”) to a principal surface (an upper surface or a lower surface) of the wafer W. In other words, the optical unit 104 is disposed such that the optical axis R of the optical unit 104 is parallel (including the meaning of “generally parallel”) to a direction orthogonal to the rotation axis G of the measurement table 102 (and preferably to intersect the rotation axis G of the measurement table 102). The optical unit 104 captures an image of an edge portion (the edge portion 80 or the notch portion 82) of the wafer W held by the measurement table 102 from a position facing the edge portion of the wafer W.

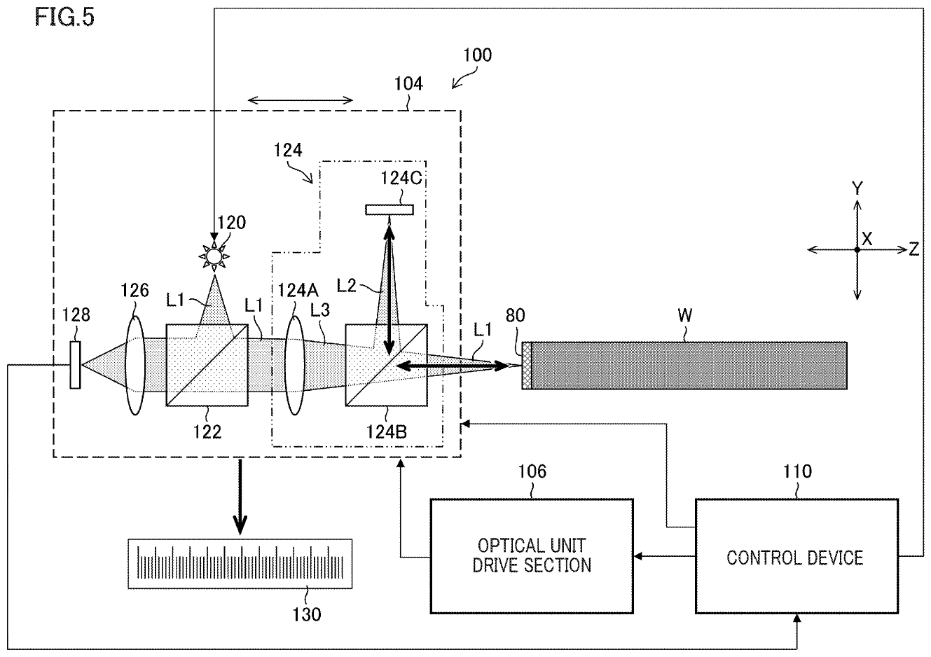

A configuration of the optical unit 104 will be described in detail. FIG. 5 is a schematic view showing details of the configuration of the optical unit 104.

The optical unit 104 is a Michelson-type white-light interference microscope. The optical unit 104 includes a light source section 120, a beam splitter 122, the interference objective lens 124, an imaging lens 126, and a camera 128, as shown in FIG. 5. The interference objective lens 124, the beam splitter 122, the imaging lens 126, and the camera 128 are arranged in this order from a surface to be measured at an edge portion of a wafer W serving as a measurement object toward the left side in the Z direction. The light source section 120 is disposed at a position facing the beam splitter 122 in the Y direction.

Under control by the control device 110, the light source section 120 emits, as measurement light L1, white light (low-coherence light having low coherent) in the form of a parallel light (collimated light) toward the beam splitter 122. Although not shown, the light source section 120 has a light source, such as a light-emitting diode, a semiconductor laser, a halogen lamp, and a high-intensity discharge lamp, capable of emitting the measurement light L1 and a collector lens which converts the measurement light L1 emitted from the light source into a parallel light.

As the beam splitter 122, for example, a half mirror is used. The beam splitter 122 reflects part of the measurement light L1 incident from the light source section 120 toward the interference objective lens 124 on the right side in the Z direction. The beam splitter 122 also transmits part of combined light L3 (to be described later) incident from the interference objective lens 124 to the left side in the Z direction and emits the combined light L3 toward the imaging lens 126.

The interference objective lens 124 is of the Michelson type, and has an objective lens 124A, a beam splitter 124B, and a reference surface 124C. The beam splitter 124B and the objective lens 124A are arranged in this order from the surface to be measured toward the left side in the Z direction. The reference surface 124C is disposed at a position facing the beam splitter 124B in the Y direction. Although an interference optical system of the Michelson type will be described below, the interference optical system is not limited to the Michelson type. A publicly known interference optical system, such as one of the Mirau type or the Linnik type, can be adopted.

The objective lens 124A has a light condensing action and condenses the measurement light L1 incident from the beam splitter 122 on the surface to be measured through the beam splitter 124B.

As the beam splitter 124B, for example, a half mirror is used. The beam splitter 124B splits the measurement light L1 incident from the objective lens 124A into a part serving as reference light L2 and the remaining part transmitted therethrough, and emits the remaining part of the measurement light L1 to the surface to be measured, and reflects the reference light L2 toward the reference surface 124C. The measurement light L1 that has passed through the beam splitter 124B is incident on the surface to be measured, is reflected by the surface to be measured, and then returns to the beam splitter 124B.

As the reference surface 124C, for example, a reflecting mirror is used. The reference surface 124C reflects the reference light L2 incident from the beam splitter 124B toward the beam splitter 124B. A Y-direction position of the reference surface 124C is manually adjustable using a position adjusting mechanism (not shown) (e.g., a ball screw mechanism or an actuator). With this adjustment, an optical path length (reference optical path length) of the reference light L2 can be adjusted.

The beam splitter 124B combines the measurement light L1 returning from the surface to be measured with the reference light L2 returning from the reference surface 124C to generate combined light L3, and directs the combined light L3 toward the objective lens 124A on the left side in the Z direction. The combined light L3 passes through the objective lens 124A and the beam splitter 122, and is incident on the imaging lens 126.

The imaging lens 126 forms an image of the combined light L3 incident from the beam splitter 122 on an imaging surface (not shown) of the camera 128. Specifically, the imaging lens 126 forms an image of a point on a focal plane of the objective lens 124A as an image point on the imaging surface of the camera 128.

Although not shown, the camera 128 has a charge coupled device (CCD) image sensor or a complementary metal oxide semiconductor (CMOS) image sensor. The camera 128 captures an image of the combined light L3 formed on an imaging surface of the image sensor by the imaging lens 126, generates a captured image signal of the combined light L3 based on the captured image, and outputs the captured image signal. The camera 128 is an example of an imaging section.

An optical unit drive section 106 includes an actuator of arbitrary type, such as a linear motor or a motor drive mechanism, and holds the optical unit 104 such that the optical unit 104 is movable in the Z direction that is the scanning direction. The optical unit drive section 106 causes the optical unit 104 to scan in the Z direction, i.e., a direction parallel to the optical axis R of the optical unit 104 under control by the control device 110. The optical unit drive section 106 is an example of a relative movement section.

The optical unit drive section 106 holds the optical unit 104 such that the optical unit 104 is movable in the Y direction and the X direction, in addition to the Z direction. This allows adjustment of a relative position (relative positions in the X and Y directions) of the optical unit 104 to an edge portion of a wafer as an object to be measured. In a case where there is a limit to a measurement field of view of a surface to be measured which can be measured at one time due to limitations on a measurement field of view and the like of the interference objective lens 124, measurement can be performed multiple times while the optical unit 104 is moved in the X direction or the Y direction. Note that the measurement table 102 may be moved in the X, Y, or Z direction instead of moving the optical unit 104 in the X, Y, or Z direction.

A scale 130 is a position detecting sensor which detects a Z-direction position of the optical unit 104, and, for example, a linear scale is used. The scale 130 repeatedly detects the Z-direction position of the optical unit 104 and repeatedly outputs the detected position to the control device 110.

FIG. 6 is a functional block diagram of the control device 110 in the shape measuring apparatus 100. The light source section 120 and the camera 128 of the optical unit 104, the scale 130, the table drive section 116, the optical unit drive section 106, an operation section 112, and the output section 114 are connected to the control device 110.

The operation section 112 includes an input device (e.g., a keyboard and a mouse) for accepting an operational input from a worker to the control device 110.

The output section 114 outputs data such as results of program execution by the control device 110, and calculation results, or the like. The output section 114 includes, for example, an operation user interface (UI) and a monitor (e.g., a liquid crystal display) for displaying a detection result. The output section 114 may include a printer, a speaker, or the like in addition to or instead of the monitor.

The control device 110 controls an operation of measuring a three-dimensional shape of a surface to be measured (the edge portion 80 or the notch portion 82) by the shape measuring apparatus 100 in response to an operational input from the operation section 112, and performs calculation and the like of the three-dimensional shape of the surface to be measured. The control device 110 includes a processor (e.g., a central processing unit (CPU) or a graphics processing unit (GPU)) which executes various types of calculations, a memory (e.g., a read only memory (ROM) and a random access memory (RAM)) serving as a work area for the processor, and a storage device (e.g., a solid state drive (SSD) or a hard disk drive (HDD)) for storing various types of programs and data.

The control device 110 functions as a shape and roughness analysis section 150, a feedback calculation section 152, and the measurement controlling section 160 when a program stored in the storage device is executed by the processor.

The measurement controlling section 160 controls the table drive section 116, the optical unit drive section 106, the light source section 120, and the camera 128. The measurement controlling section 160 causes the camera 128 to repeatedly capture an image of a surface to be measured (the edge portion 80 or the notch portion 82) of a measurement object at fixed intervals while the optical unit 104 scans in the scanning direction (Z direction). Specifically, the measurement controlling section 160 controls the table drive section 116 to rotate the measurement table 102 such that the surface to be measured (the edge portion 80 or the notch portion 82) of the measurement object is positioned to face the optical unit 104. After emission of the measurement light L1 from the light source section 120 is started, the measurement controlling section 160 controls the optical unit drive section 106 to cause the optical unit 104 to scan in the Z direction. While the optical unit drive section 106 causes the optical unit 104 to scan in the Z direction, the measurement controlling section 160 repeatedly executes capturing of an image of combined light L3 by the camera 128 and outputting of the captured image to the control device 110 for every movement of the optical unit 104 in the Z direction by the fixed length based on a result of detecting the Z-direction position of the optical unit 104 by the scale 130.

Every time the camera 128 captures the image of the combined light L3, the shape and roughness analysis section 150 acquires the captured image output from the camera 128 and generates three-dimensional shape data of a surface to be measured of a measurement object (a wafer W). The shape and roughness analysis section 150 generates three-dimensional shape data of a tip portion of a truer when the truer is placed on the measurement table 102 in the measurement section 20.

The feedback calculation section 152 performs feedback control in accordance with a measurement result from the shape and roughness analysis section 150.

### EXAMPLE 1

External measurement by a device different from a wafer grinding section has been required to detect deterioration (measure the degree of wear) of a truer, and the work of detecting truer deterioration has been cumbersome. To avoid cumbersome work, count-based management in which the truer is replaced when the number of grinding wheels ground by the truer reaches a predetermined number, has been conducted.

However, in a case where a truer is replaced based solely on the number of grinding wheels processed, regardless of an actual condition of deterioration of the truer, an undeteriorated truer may be replaced.

For this reason, in Example 1, a truer is periodically measured in the wafer processing system 10. For example, each time a fixed time elapses after the start of operation of the wafer processing system 10 or each time the number of times the grinding wheel 34 or the grinding wheel for precision grinding is processed using the truer reaches a predetermined number, the truer is transported to the measurement section 20, and a shape of a tip portion of the truer is measured.

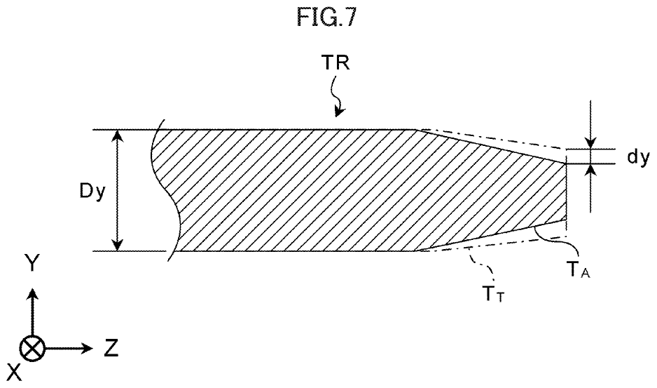

FIG. 7 is a cross-sectional view showing an example of a shape of a tip portion of a truer. Let dy be the magnitude of a wear amount that is a difference between an actual measured shape T_{A} of a truer TR measured by the shape measuring apparatus 100 and a target shape T_{T} (a deviation in the Y direction, a maximum value of the deviation).

The shape and roughness analysis section 150 generates three-dimensional shape data of the tip portion of the truer TR and calculates the wear amount dy.

The feedback calculation section 152 responds to the measurement result from the shape and roughness analysis section 150. In a case where the wear amount dy exceeds a threshold (e.g., 5 μm), the feedback calculation section 152 outputs (e.g., displays) a message to indicate that the truer TR needs to be replaced to the output section 114 or stops processing of a wafer W. Note that the threshold is not limited to the above-described value and that the truer TR may be determined to be defective (deteriorated, or not good), for example, in a case where percentage (ratio) of dy to a thickness Dy of the wafer W is equal to or more than the threshold (1%, for example).

According to Example 1, since a truer is periodically measured, the degree of wear of the truer can be parameterized and numerically evaluated. This allows reduction of unnecessary maintenance of the truer TR and prevention of replacement of the undeteriorated truer TR. According to Example 1, it is possible to reduce the probability of occurrence of poor processing of the wafer W and enhance the reliability of processing.

### EXAMPLE 2

In a case where measurement result of a shape of a wafer W shows that the shape is defective (no good), prompt identification of the cause and restoration to a normal state are required. Examples of possible approaches to be taken to the case where the shape of the wafer W is defective (outside an allowable range) include the following one. That is, after the grinding wheel 34 or the grinding wheel for precision grinding is ground with a truer TR, the wafer W is ground and measured again. In a case where the redetermination result shows that the shape of the wafer W is defective, the truer TR and the like are replaced.

The above-described approach, however, processes from grinding wheel maintenance to redetermination becomes wasted in a case where the truer TR is defective (deteriorated).

Under the circumstances, in Example 2, the truer TR is measured in a case where a shape of the wafer W is defective (not good). This eliminates waste in grinding wheel maintenance.

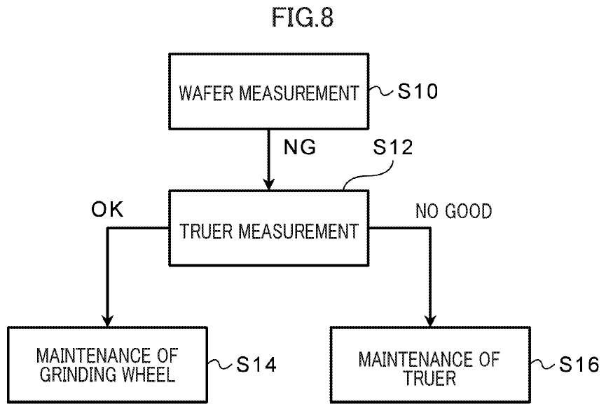

FIG. 8 is a flowchart showing a wafer processing method according to Example 2.

As shown in FIG. 8, in Example 2, a shape of an edge portion of the wafer W is first measured by the shape measuring apparatus 100 (step S10). In a case where a measurement result indicates that the wafer W is defective, the truer TR used for maintenance (truing) of the grinding wheel 34 or the grinding wheel for precision grinding that has ground the wafer W is transported to the measurement section 20, and a shape of a tip portion of the truer TR is measured by the shape measuring apparatus 100 (step S12).

In a case where the shape of the tip portion of the truer TR is conforming (OK), the truer TR is used to maintain the grinding wheel 34 or the grinding wheel for precision grinding (step S14). On the other hand, in a case where the shape of the tip portion of the truer TR is defective (deteriorated, not good), maintenance of the truer TR is performed (step S16). For example, the feedback calculation section 152 gives notification (e.g., provides a display encouraging replacement of the truer TR) to an operator via the output section 114 so as to prevent truing.

According to Example 2, processes from truing to remeasurement of the wafer W can be skipped. This allows early identification of the cause of defect in the shape of the wafer W. In Example 2, truing by the deteriorated truer TR is not performed, and the grinding wheel 34 or the grinding wheel for precision grinding is not damaged. It is thus possible to reduce a running cost of the wafer processing system 10.

### EXAMPLE 3

As described above, in the wafer processing system 10, a shape of a truer TR is transferred onto the grinding wheel 34 or the grinding wheel for precision grinding, and the grinding wheel 34 or the grinding wheel for precision grinding is used to grind a wafer W. Thus, the wafer W and the truer TR preferably have as similar shapes to each other as possible, more preferably the same shapes.

For this reason, Example 3 provides a user interface (UI) which superimposes and displays measurement results of the wafer W and the truer TR on the output section 114.

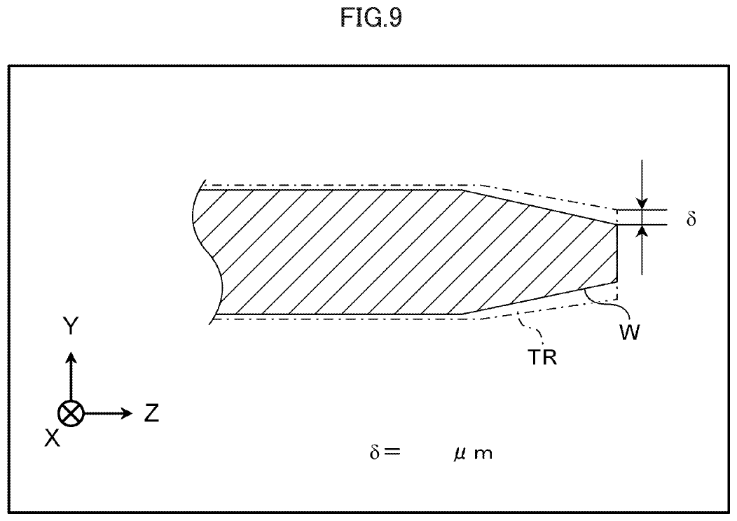

In an example shown in FIG. 9, the measurement results (sectional shapes) of the wafer W and the truer TR are superimposed and displayed. Note that numerical values of dimensions (e.g., Y-direction dimensions or inclination angles) of the wafer W and the truer TR or an amount δ of deviation in the Y direction (e.g., a maximum value of deviation) may be displayed.

Example 3 allows an operator to confirm a difference in shape between the wafer W and the truer TR based on the above-described UI. It is thus possible to determine whether the shape of the truer TR has been accurately transferred onto the wafer W. In a case where the wafer W is disfigured, whether the truer TR has a problem can be determined.

Note that processing conditions (e.g., a feed in the Z direction) for the wafer W and the like may be displayed together. In this case, the cause of defect of the wafer W can be determined by comparing the shape and a feed in the Z direction of the truer TR with those of the wafer W.

### First Modification

The upper and lower sides of the edge portion 80 of a wafer W may be separately processed by (vertically) moving a relative position between the grinding wheel 34 and the wafer W in a Y direction. In this case, it is impossible to determine whether defect of a shape of the wafer W results from movement in the Y direction or results from a shape of the grinding wheel 34 (dressing). For example, if truing is conducted in a case where defect is caused by the movement in the Y direction, actual shapes of the truer TR and the wafer W may become far different from each other to reduce processing accuracy of the wafer W.

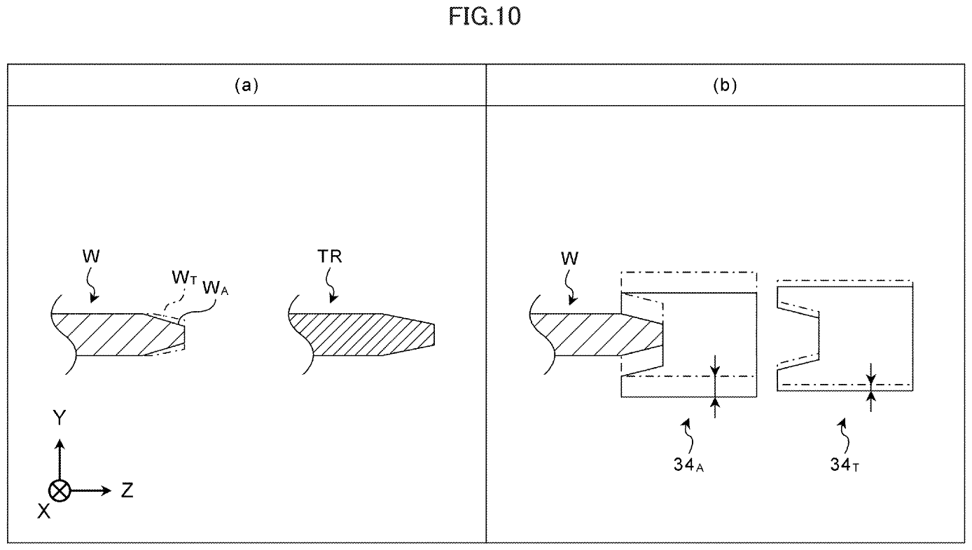

FIG. 10 is a view for explaining the cause of defect in a shape of a wafer. Part (a) of FIG. 10 shows an example in which an actual shape W_{A} of the wafer W is far different from a target shape W_{T} due to wear of the truer TR. Part (b) of FIG. 10 shows an example in which the wafer W becomes far different (become thinner) from a target shape because an actual movement amount 34_{A} is excessively larger than a target relative movement amount 34_{T} between a grinding wheel and the wafer W.

For this reason, in a first modification, the feedback calculation section 152 calculates a correction amount and a Y-direction movement amount of the truer TR independently of each other, by comparing a measured value and a design value of a shape of the truer TR. For example, in a case where defect in the shape of the wafer W is detected, the truer TR is measured in the measurement section 20. In a case where a difference between the measured value and the design value of the shape is determined to be equal to or more than a threshold by the feedback calculation section 152, the shape of the truer TR may be corrected or the truer TR may be replaced in accordance with the difference. On the other hand, in a case where the difference is determined to be less than the threshold by the feedback calculation section 152, the wafer/grinding wheel position controlling section 26 may be controlled via the device controlling section 200 such that a relative movement amount between the wafer W and the grinding wheel may be adjusted in accordance with the difference. After such adjustments, whether the shape of the wafer W is defective or not may be determined again.

According to the first modification, it is possible to appropriately conduct correction of the shape of the truer TR and correction of the relative movement amount between the wafer W and the grinding wheel.

As described above, since the wafer W and the truer TR are measured using the identical measurement section 20 in the present embodiment, a systematic error is unlikely to be included in a measurement result, and a movement amount can be corrected with high accuracy.

### Second Modification

Although processing efficiency increases with increase in a depth of cut (a movement amount in a Z direction) of the grinding wheel 34 into a wafer W, a ground surface (hereinafter referred to as a processed surface) of the wafer W becomes rougher.

For this reason, in a second modification, roughness of the processed surface of the wafer W is measured by the shape measuring apparatus 100. The feedback calculation section 152 provides feedback on the depth of cut of the grinding wheel 34 and the like in accordance with a measurement result of the roughness. For example, when the roughness of the processed surface of the wafer W increases, the feedback calculation section 152 controls the wafer/grinding wheel position controlling section 26 via the device controlling section 200 to perform at least one of: adjustment that reduces the depth of cut; and adjustment that increases the number of revolutions (rotational speed) of the spindle motor 36.

According to the second modification, through utilization of a measurement result of the roughness of the wafer W, processing can be performed with a maximum depth of cut that allows a target roughness to be achieved in accordance with the state of a grinding wheel. This contributes to improvement of the economics of the wafer processing system 10.

### Third Modification

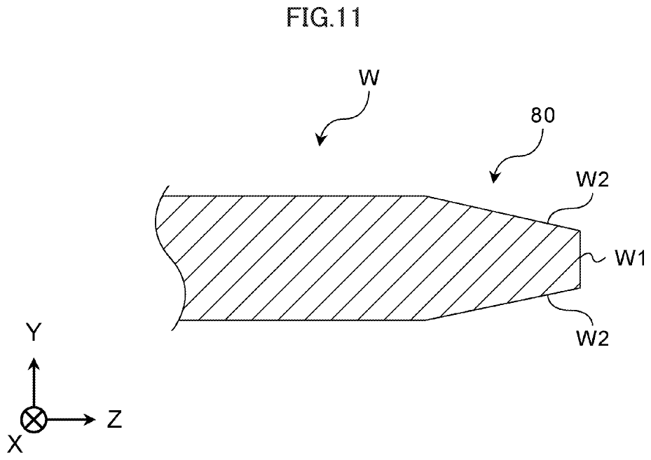

FIG. 11 is a cross-sectional view of a wafer W after grinding. As shown in FIG. 11, after grinding, the edge portion 80 of the wafer W is formed to have: a generally planar portion W1 extending along the Y direction; and inclined surface portions W2 extending from upper and lower end portions of the generally planar portion W1 in the Y direction, toward the front surface and the back surface of the wafer W, respectively, in conformity with the shape of the grinding wheel 34.

In a third modification, the feedback calculation section 152 compares roughness of each inclined surface portion W2 and that of the generally planar portion W1, and provides the comparison result as feedback such that the feedback is incorporated into processing conditions of the wafer W. For example, since processing stress is likely to be applied to each inclined surface portion W2 of the wafer W, a surface of a grinding wheel is likely to become rough. In contrast, the roughness of the generally planar portion W1 tends to be stable.

In view of the above-described property, the feedback calculation section 152 controls the wafer/grinding wheel position controlling section 26 via the device controlling section 200 to adjust a depth of cut of the grinding wheel 34, the number of revolutions (rotational speed) of the spindle motor 36, and the like in a case where the roughness of the generally planar portion W1 increases. Specifically, the generally planar portion W1 can be inhibited from becoming rough by reducing the depth of cut of the grinding wheel 34 or increasing the number of revolutions of the spindle motor 36.

In a case where the roughness of each inclined surface portion W2 increases, the feedback calculation section 152 performs at least one of: truing; and outputting of a message encouraging an operator to conduct truing or replace a truer TR to the output section 114.

According to the third modification, it is possible to process the wafer W under optimum processing conditions in accordance with the roughness of the generally planar portion W1 and those of the inclined surface portions W2 of the wafer W.

### Fourth Modification

In a case where processing is performed with the grinding wheel 34 inclined with respect to a wafer W, it is possible to correct a helical angle in accordance with a measurement result of the wafer W by the shape measuring apparatus 100.

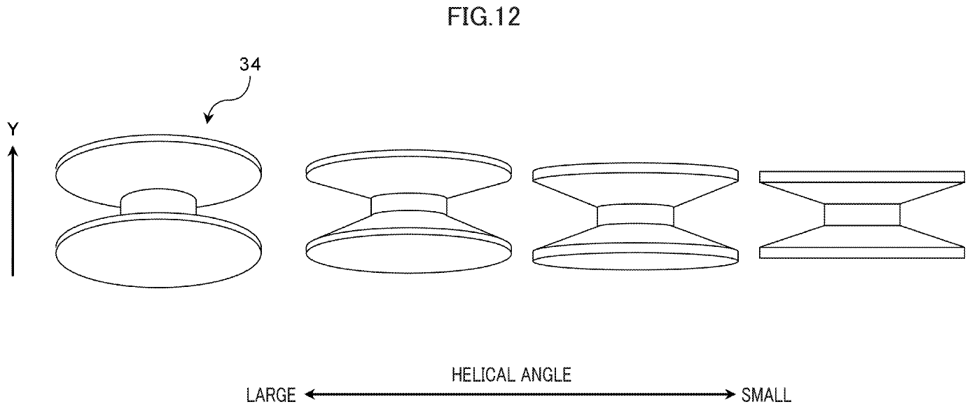

For example, a change of the helical angle may change shapes of processed surfaces (W1 and W2) of the wafer W or improve roughness. For this reason, the feedback calculation section 152 may control the wafer/grinding wheel position controlling section 26 via the device controlling section 200 to adjust the helical angle in a case where the shapes or the roughness of the processed surfaces of the wafer W become deteriorated, as shown in FIG. 12.

According to the present embodiment, it is possible to process the wafer W under optimum conditions by providing feedback in accordance with a measurement result of the wafer W or a truer TR. Since an operator can be immediately notified of the need for maintenance via the output section 114, poor processing can be reduced.

Additionally, according to the present embodiment, since the truer TR and the wafer W are measured by the identical measurement section 20, it is possible to curb influence of a systematic error of the measurement section 20 at the time of feedback.

In the present embodiment described above, configurations which include a shape measuring apparatus having a white-light interference microscope in the measurement section 20 have been described as examples. The present invention, however, is not limited to this. For example, a configuration which includes a shape measuring apparatus having a microscope, such as a focus variation type microscope or a laser confocal type microscope, or a configuration which includes a shape measuring apparatus using a light projection measurement method may be adopted.

The embodiment of the present invention has been described above. The present invention, however, is not limited to the above-described examples, and various changes or modifications may be made thereto without departing from the scope of the present invention.

### REFERENCE SIGNS LIST

10 wafer processing system, 12 cassette section, 14 loading section, 16 grinding section, 18 cleaning section, 20 measurement section, 22 transfer section, 24 grinding wheel motor, 26 wafer/grinding wheel position controlling section, 30 grinding apparatus, 32 grinding table, 32a holding surface, 34 grinding wheel, 34a grinding groove, 36 spindle motor, 80 edge portion, 82 notch portion, 100 shape measuring apparatus, 102 measurement table, 102a holding surface, 104 optical unit, 106 optical unit drive section, 110 control device, 112 operation section, 114 output section, 116 table drive section, 120 light source section, 122 beam splitter, 124 interference objective lens, 124A objective lens, 124B beam splitter, 124C reference surface, 126 imaging lens, 128 camera, 130 scale, 150 shape and roughness analysis section, 152 feedback calculation section, 160 measurement controlling section, 200 device controlling section

What is claimed is:

1. A wafer processing system comprising:
a grinding section configured to perform grinding of an edge portion of a wafer;
a measurement section configured to measure a shape of the edge portion of the wafer subjected to grinding, the measurement section being configured to measure a shape of a tip portion of a truer for truing a grinding wheel used for the grinding; and
a feedback calculation section configured to perform feedback control for the grinding based on a measurement result of the shape of the tip portion of the truer.

2. The wafer processing system according to claim 1, wherein the feedback calculation section determines whether the truer is defective or not in a case where a wear amount of the truer exceeds a threshold.

3. The wafer processing system according to claim 1, wherein
the measurement section measures the shape of the tip portion of the truer in a case where the feedback calculation section determines that the shape of the edge portion of the wafer is defective,
the feedback calculation section produces output encouraging maintenance of the truer in a case where the feedback calculation section determines that the shape of the tip portion of the truer is defective, and
the feedback calculation section produces output encouraging maintenance of the grinding wheel using the truer in a case where the feedback calculation section determines that the shape of the tip portion of the truer is not defective.

4. The wafer processing system according to claim 1, comprising
an output section configured to display measurement results of the wafer and the truer in a superimposed manner.

5. The wafer processing system according to claim 1, wherein the feedback calculation section compares a measured value and a design value of the shape of the truer and calculates a correction amount for the shape of the truer and a relative movement amount between the wafer and the grinding wheel.

6. The wafer processing system according to claim 1, wherein
the measurement section measures a surface roughness of a ground surface of the wafer, and
the feedback calculation section adjusts a depth of cut of the grinding wheel into the wafer in accordance with a measurement result of the surface roughness of the ground surface.

7. The wafer processing system according to claim 1, wherein the feedback calculation section adjusts a helical angle of the grinding wheel in accordance with a measurement result of the wafer.

8. A wafer processing method comprising:
measuring a shape of a tip portion of a truer used for grinding, in a measurement section configured to measure a shape of an edge portion of a wafer subjected to grinding; and
perform feedback control for the grinding based on a measurement result of the shape of the tip portion of the truer.
